(19) United States
(12) Patent Application Publication
(10) Pub. No.: US 2009/0117274 A1
(43) Pub. Date: May 7, 2009

(54) SOLUTION BASED LANTHANUM PRECURSORS FOR ATOMIC LAYER DEPOSITION

(76) Inventors: Ce Ma, San Diego, CA (US); Kee-Chan Kim, Carlsbad, CA (US); Graham Anthony McFarlane, Carlsbad, CA (US)

Correspondence Address: The BOC Group, Inc., 575 MOUNTAIN AVENUE, MURRAY HILL, NJ, 07974-2082, US

(21) Appl. No.: 12/261,169

(22) Filed: Oct. 30, 2008

Related U.S. Application Data
(60) Provisional application No. 61/001,969, filed on Nov. 6, 2007.

(51) Int. Cl. C23C 16/00; C07F 5/00

(52) U.S. Cl. 427/255.28; 534/15

(57) ABSTRACT

Alkyl cyclopentadienyl precursors for use in ALD processes are disclosed. The present invention particularly relates to La alkyl cyclopentadienyl precursors, such as tris(isopropyl-cyclopentadienyl) Lanthanum.

### CROSS REFERENCE TO RELATED APPLICATIONS

This application claims priority from U.S. Provisional Patent Application Ser. No. 61/001,969 filed Nov. 6, 2007.

### FIELD OF THE INVENTION

The present invention relates to new and useful solution based precursors for atomic layer deposition.

### BACKGROUND OF THE INVENTION

Atomic layer deposition (ALD) is an enabling technology for advanced thin-film deposition, offering exceptional thickness control and step coverage. In addition, ALD is an enabling technique that will provide the next generation conductor barrier layers, high-k gate dielectric layers, high-k capacitance layers, capping layers, and metallic gate electrodes in silicon wafer processes. ALD-grown high-k and metal gate layers have shown advantages over physical vapor deposition and chemical vapor deposition processes. ALD has also been applied in other electronics industries, such as flat panel display, compound semiconductor, magnetic and optical storage, solar cell, nanotechnology and nanomaterials. ALD is used to build ultra thin and highly conformal layers of metal, oxide, nitride, and others one monolayer at a time in a cyclic deposition process. Oxides and nitrides of many main group metal elements and transition metal elements, such as aluminum, titanium, zirconium, hafnium, and tantalum, have been produced by ALD processes using oxidation or nitridation reactions. Pure metallic layers, such as Ru, Cu, Ta, and others may also be deposited using ALD processes through reduction or combustion reactions.

The widespread adoption of ALD processes faces challenges in terms of a restricted selection of suitable precursors, low wafer throughput, and low chemical utilization. Many ALD precursors useful in HKMG exist in the solid phase with relatively low volatility. To meet these challenges, the present invention develops a solution-precursor-based ALD technology called Flex-ALD™. With solution-based precursor technology, ALD precursor selection is considerably broadened to include low-volatility solid precursors, wafer throughput is increased with higher film growth rates, and chemical utilization is improved via the use of dilute chemistries. In addition, liquid injection with vapor pulses provides consistent precursor dosage.

A typical A/D process uses sequential precursor gas pulses to deposit a film one layer at a time. In particular, a first precursor gas is introduced into a process chamber and produces a monolayer by reaction at surface of a substrate in the chamber. A second precursor is then introduced to react with the first precursor and form a monolayer of film made up of components of both the first precursor and second precursor, on the substrate. Each pair of pulses (one cycle) produces one monolayer or less of film allowing for very accurate control of the final film thickness based on the number of deposition cycles performed.

As semiconductor devices continue to get more densely packed with devices, channel lengths also have to be made smaller and smaller. For future electronic device technologies, it will be necessary to replace SiO₂ and SiON gate dielectrics with ultra thin high-k oxides having effective oxide thickness (EOT) less than 1.5 nm. Preferably, high-k materials should have high band gaps and band offsets, high k values, good stability on silicon, minimal SiO₂ interface layer, and high quality interfaces on substrates. Amorphous or high crystalline temperature films are also desirable.

Materials based on lanthanum (a) can play an important role in next-generation high-k/metal gate (HKMG) stacks. A critical issue in realizing low effective oxide thickness of promising high-k dielectrics is finding suitable metal gate electrodes with matched work functions (WF) free of Fermi pinning. Recent studies show that La can be used both as a high-k layer in oxide form or as a mid-gap metal gate to effectively lower the WF in N-MOSFET stacks. A La incorporated MG stack can reduce interfacial charges and therefore eliminate Fermi pinning effects.

Several types of traditional vapor phase deposition precursors have been tested in ALD processes, including halides, alkoxides, β-diketonates, and newer alkylamides and cyclopentadienyls materials. Halides perform well in ALD processes with good self-limiting growth behaviors, but are mostly high melting solids that require high source temperatures. Another disadvantage of using solid precursors is the risk of particle contamination to the substrate. In addition, there is an issue of instability in flux or dosage associated with the solid precursors. Alkoxides show reduced deposition temperatures in ALD processes, but can decompose in the vapor phase leading to a continuous growth process instead of ALD. β-diketonates are used in MOCVD processes and are generally more stable towards hydrolysis than alkoxides. However, they are less volatile and require high source and substrate temperatures. A mixed ligand approach with β-diketonates and alkoxides has been suggested to improve stability of alkoxide MOCVD precursors. Examples are Zr(acac)₂(hfip)₂, Zr(O-t-Pr)₂(thd)₂. In addition, metal nitrate precursors, M(NO₃)ₓ, alkylamides, and amidinates, show self-limiting growth behavior with very low carbon or halide contamination. However, the stability of nitrates and amides is an issue in production and many cyclopentadienyls are in solid forms.

In general, ALD precursors should have good volatility and be able to saturate the substrate surface quickly through chemisorptions and surface reactions. The ALD half reaction cycles should be completed within 5 seconds, preferably within 1 second. The exposure dosage should be below 10⁸ Laugmuir (1 Torr*sec=10⁶ Laugmuir). The precursors should be stable within the deposition temperature windows, because un-controllable CVD reactions could occur when the precursor decomposes in gas phase. The precursors themselves should also be highly reactive so that the surface reactions are fast and complete. In addition, complete reactions yield good purity in films. The preferred properties of ALD precursors are given in Table 1.

TABLE 1
Preferred ALD Precursor Properties

| Requirement | | |
|---|---|---|
| Class | Property | Range |
| Primary | Good volatility | >0.1 Torr |
| Primary | Liquid or gas | At room temperatures |
| Primary | Good thermal stability | >250° C. or >350° C. in gas |
| | | phase |
| Primary | Fast saturation | <5 sec or <1 sec |
| Primary | Highly reactive | Complete surface reactive cycles |
| Primary | Non reactive volatile | No product and reagent reaction |
| | byproduct | |
| Secondary | High growth rate | Up to a monolayer a cycle |
| Secondary | Less shield effect from | Free up un-occupied sites |
| | ligands | |
| Secondary | Cost and purity | Key impurity: H₂O, O₂ |
| Secondary | Shelf-life | >1-2 years |
| Secondary | Halides | Free in films |
| Secondary | Carbon | <1% in non carbon containing |
| | | films |

Because of stringent requirements for ALD precursors as noted in Table 1, new types of ALD precursors are needed that are more stable, exhibit higher volatility, and are better suited for ALD. However, the cost of developing new precursors is a significant obstacle.

Examples of solvents useful in accordance with the above co-pending application are given in Table 2.

TABLE 2
Examples of Solvents

| Name | Formula | BP@760 Torr (° C.) |
|---|---|---|
| Dioxane | C₄H₈O₂ | 101 |
| Toluene | C₇H₈ | 110.6 |
| n-butyl acetate | CH₃CO₂(n-Bu) | 124-126 |
| Octane | C₈H₁₈ | 125-127 |
| Ethylcyclohexane | C₈H₁₆ | 132 |
| 2-Methoxyethyl acetate | CH₃CO₂(CH₂)₂OCH₃ | 145 |
| Cyclohexanone | C₆H₁₀O | 155 |
| Propylcyclohexane | C₉H₁₈ | 156 |
| 2-Methoxyethyl Ether | (CH₃OCH₂CH₂)₂O | 162 |
| (diglyme) | | |
| Butylcyclohexane | C₁₀H₂₀ | 178 |

There remains a need in the art for improvements to solvent based ALD precursors.

### SUMMARY OF THE PRESENT INVENTION

The present invention provides improved solvent based precursor formulations. In particular, the present invention provides alkyl cyclopentadienyl precursors for use in ALD processes. Particularly useful La alkyl cyclopentadienyl precursors, such as tris(isopropyl-cyclopentadienyl) Lanthanum are provided by the present invention.

### BRIEF DESCRIPTION OF THE DRAWINGS

FIG. 1 is a schematic drawing showing a delivery system for the ALD precursors according to the present invention.

### DETAILED DESCRIPTION OF THE INVENTION

The present invention provides La-based materials for HKMG applications. A solid La precursor is dissolved in a solvent blend. The precursor formulation is delivered via a direct liquid injection method to a vaporizer and the fully vaporized solution precursors are then pulsed into a deposition chamber with an in situ quartz crystal microbalance. High-k bi-layers are formed by depositing a La oxide ALD layer over a hafnium oxide surface on a silicon wafer sample. Moisture is used as the co-reactant. Growth rates on the order of 0.6-1 Å per cycle are realized. Composition analysis showed carbon and other contaminants are below 1 atomic %.

The present invention provides alkyl cyclopentadienyl precursors for use in ALD processes. Several useful La alkyl cyclopentadienyl precursors have been identified by the present invention as discussed below.

Lanthanum(III)isopropoxide or La(OPrⁱ)₃ was studied in accordance with the above procedures. Thermogravimetric analysis (TGA) was used to measure weight changes in the material as a function of temperature under a controlled atmosphere to determine thermal stability and composition. TGA analysis of a La(OPrⁱ)₃ precursor showed a relatively high residual mass at temperatures greater than 300° C. indicating that complete vaporization was not achieved. However, deposition of ALD layers was accomplished at deposition temperatures of 300° C. to 350° C. and vaporizer temperatures of 180° C. to 230° C. with growth rates of 0.1 Å/cycle. The thinness of the film did not allow for composition of the deposited layer to be measured.

Tris(N,N-bis(trimethylsilyl)amide) Lanthanum or La(N(TMS)₂)₃ was also studied. TGA analysis of analysis of a La(N(TMS)₂)₃ precursor showed nearly complete vaporization at relatively low temperatures of 220° C. although some decomposition was experienced at temperatures starting at 100° C. Deposition of ALD layers at deposition temperatures of 250° C. to 300° C. and vaporizer temperatures of 80° C. to 180° C. resulted in growth rates of 1.2 to 1.5 Å/cycle. The resulting film was composed of mainly La and O and was harder at lower vaporization temperatures because of less decomposition.

Tris(cyclopentadienyl) Lanthanum or La(CP)₃ was studied. TGA analysis of analysis indicated nearly complete vaporization at temperatures of 370° C. with very low residual mass. However, solubility of this precursor is low making deposition difficult.

Of particular interest the present invention studied Tris(isopropyl-cyclopentadienyl) Lanthanum or La(CP′)₃. TGA analysis of analysis of a La(CP′)₃ shows nearly complete vaporization at less than 300° C. with low residual mass. Deposition of ALD layers at growth rates from 0.6 to 6 Å/cycle were achieved at deposition temperatures of 200° C. to 300° C. and vaporizer temperatures of 145° C. to 23° C. The precursor formulation was easy to work with, easy to deliver to the vaporizer and exhibited no decomposition in the vaporizer. In one study a 0.1 M La(CP′)₃ solution mixture was used with deposition carried out at a fixed deposition temperature of 300° C., but with vaporizer temperatures ranging from 145° C. to 190° C. Growth rates were lower at lower vaporizer temperatures and some trace residue was found in the vaporizer after testing. The deposited films exhibited excellent composition having high lanthanum oxide purity and very low carbon content. Because reaction between La₂O₃ and moisture is thermodynamically favorable, it is important to protect the film during deposition. Table 3 shows composition makeup for two deposited films made using the La(CP′)₃ precursor according to the present invention and clearly show good lanthanum oxide formation.

TABLE 3
Test Results for La(CP′)₃ Precursor - 0.1M Concentration

| | Deposition T | Vaporizer T | O | La | C |
|---|---|---|---|---|---|
| Test | (° C.) | (° C.) | % atomic | % atomic | % atomic |
| 1 | 300 | 140 | 61.8 | 27.3 | 10.9 |
| 2 | 300 | 145 | 67.3 | 32.1 | 0.6 |
| 3 | 300 | 150 | 67.3 | 61.8 | 0.6 |
| 4 | 300 | 180 | 66.9 | 32.9 | 0.2 |

A separate deposition carried out with a 0.22M concentration solution at a deposition temperature of 300° C. and a vaporizer temperature of 150° C. provided higher growth rates and exhibited content of 67.7 atomic % oxygen, 29.4 atomic % lanthanum and 2.9 atomic % carbon.

Table 4 sets forth test results for different solutions of the La(CP′)₃ precursor according to the present invention.

TABLE 4
Test Results for La(CP′)₃ Precursor

| Solution # | 1 | 2 | 3 |
|---|---|---|---|
| Concentration (M) | 0.1 | 0.1 | 0.22 |
| Viscosity (cP) | 0.54 | 0.39 | 0.44 |
| Liquid Flow @ RT | ~50 | ~70 | ~60 |
| (μl/min) | | | |
| Vaporizer T (° C.) | 145-230 | 140-190 | 140-190 |
| Deposition T (° C.) | 200-300 | 300 | 300 |
| Growth Rate | 0.6-6 | 0.7-4 | 1-6 |
| (Å/cycle) | | | |

The selection of solvents and additives is critical to ALD precursor solutions. They must not interfere with ALD process in either the gas phase or on the substrate surface. The solvents and additives should also be thermally robust without any decomposition at ALD processing temperatures.

Hydrocarbons are generally chosen as primary solvents to dissolve ALD precursors by means of agitation or ultrasonic mixing if necessary. Hydrocarbons are chemically inert and compatible with the precursors and do not compete with the precursors for reaction sites on the substrate surface. The boiling point of the solvents should be high enough to match the volatility of the solute in order to avoid particle generation during the vaporization process. Preferred concentration for the La(CP′)₃ precursor is 0.1M and the preferred solvents are alkanes, in particular a blend of octane and heptane.

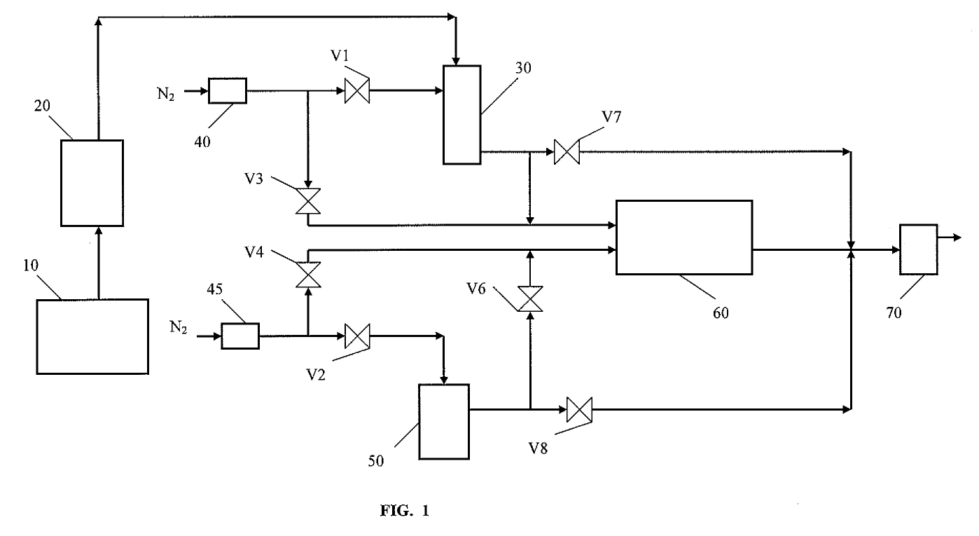

FIG. 1 is a schematic drawing showing a delivery system for the precursor solutions according to the present invention. In particular, the delivery system of the present invention includes a precursor solution source 10, connected through a liquid pump 20, to a vaporizer 30. The vaporizer 30, vaporizes the received precursor solution and then delivers such to a deposition chamber 60, which is connected to a system pump 70. A first mass flow controller 40, having a nitrogen source can supply nitrogen to the vaporizer 30, through a first ALD valve V1, or to the deposition chamber 60, through metering valve V3. A second mass flow controller 45, having a nitrogen supply can supply nitrogen to a water source 50, through a second ALD valve V2, or directly to the deposition chamber 60, through metering valve V4. A further metering valve V7, allows for vapor bypass from the vaporizer 30, to the system pump 70. An on/off valve V6, connects the water source 50, to the deposition chamber 60, and another metering valve V8, allows for water bypass from the water source 50, to the system pump 70.

In operation, the system according to the present invention provides ALD deposition of lanthanum oxide in the following manner. A precursor solution according to the present invention, e.g. La(CP′)₃ is pumped by liquid pump 20, from the precursor source 10, to the vaporizer 30, where it is vaporized. The vaporized precursor is then pulsed into the deposition chamber 60, as controlled by the mass flow controller 40, in conjunction with ALD valve V1. The co-reactant moisture is then supplied from water source 50, to the deposition chamber 60, as controlled by the mass flow controller 45, in conjunction with ALD valve V2 and on/off valve V6. The metering valves V3, V4, V7 and V8, allow for purging of the system and bypass of the deposition chamber 60.

The present invention provides improved solvent based lanthanum precursor formulations, including La alkyl cyclopentadienyl precursors, such as tris(isopropyl-cyclopentadienyl) Lanthanum. The precursor solutions according to the present invention are capable of producing superior lanthanum oxide layers for use in next-generation high-k/metal gate stacks.

It is anticipated that other embodiments and variations of the present invention will become readily apparent to the skilled artisan in the light of the foregoing description, and it is intended that such embodiments and variations likewise be included within the scope of the invention as set out in the appended claims.

What is claimed:

1. A precursor for atomic layer deposition comprising a lanthanum alkyl cyclopentadienyl compound.

2. A precursor according to claim 1 comprising lanthanum(III) isopropoxide, tris(N,N-bis(trimethylsilyl)amide) lanthanum, tris(cyclopentadienyl) lanthanum, or tris(isopropyl-cyclopentadienyl) lanthanum.

3. A precursor according to claim 2 comprising tris(isopropyl-cyclopentadienyl) lanthanum.

4. A lanthanum oxide layer deposited by atomic layer deposition using a precursor comprising a lanthanum alkyl cyclopentadienyl compound.

5. A lanthanum oxide layer according to claim 4 wherein the lanthanum alkyl cyclopentadienyl compound is lanthanum(III)isopropoxide, tris(N,N-bis(trimethylsilyl)amide) lanthanum, tris(cyclopentadienyl) lanthanum, or tris(isopropyl-cyclopentadienyl) lanthanum.

6. A lanthanum oxide layer according to claim 5 wherein the lanthanum alkyl cyclopentadienyl compound is tris(isopropyl-cyclopentadienyl) lanthanum.

7. A method of depositing a lanthanum oxide layer comprising performing atomic layer deposition using a precursor comprising a lanthanum alkyl cyclopentadienyl compound.

8. A method according to claim 7 wherein the lanthanum alkyl cyclopentadienyl compound is lanthanum(III)isopropoxide, tris(N,N-bis(trimethylsilyl)amide) lanthanum, tris(cyclopentadienyl) lanthanum, or tris(isopropyl-cyclopentadienyl) lanthanum.

9. A method according to claim 8 wherein the lanthanum alkyl cyclopentadienyl compound is tris(isopropyl-cyclopentadienyl) lanthanum.
